(19) United States
(12) Patent Application Publication
(10) Pub. No.: US 2010/0163837 A1
(43) Pub. Date: Jul. 1, 2010

(54) GUNN DIODE

(75) Inventors: Oktay Yilmazoglu, Gross-Zimmern (DE); Kabula Mutamba, Alsbach-Haehnlein (DE); Dimitris Pavlidis, Eschborn (DE); Tamer Karduman, Erzhausen (DE)

Correspondence Address: LEYDIG, VOIT AND MAYER, TWO PRUDENTIAL PLAZA, SUITE 4900, 180 NORTH STETSON AVENUE, CHICAGO, IL, 60601, US

(73) Assignee: Technische Universitaet Darmstadt, Darmstadt (DE)

(21) Appl. No.: 12/526,534

(22) PCT Filed: Jan. 31, 2008
(86) PCT No.: PCT/EP2008/000772

§ 371 Date: Mar. 12, 2010

(30) Foreign Application Priority Data
Feb. 9, 2007 (JP) 10 2007 007 159.2

(51) Int. Cl. H01L 47/02

(52) U.S. Cl. 257/6; 250/370.12; 257/E47.004

(57) ABSTRACT

A Gunn diode includes an active layer having a top and a bottom, a first contact layer disposed adjacent to the top of the active layer, a second contact layer disposed adjacent to the bottom of the active layer, wherein the first and second contact layers are more heavily doped than the active layer, and at least one outer contact layer disposed at an outer region of at least one of the first and second contact layers, the at least one outer contact layer being more heavily doped than the first and second contact layers, wherein the first and second contact layers, the active layer, and the at least one outer contact layer include a base material that is the same.

This is a U.S. National Phase Application under 35 U.S.C. §371 of PCT/EP2008/000772, filed on Jan. 31, 2008, which claims priority to German Application No. DE 102007007159.2, filed on Feb. 9, 2007, both of which are incorporated by reference herein. The International Application was published in German as WO 2008/095639 on Aug. 14, 2008 under PCT article 21 (2).

The invention relates to a Gunn diode, wherein the top and the bottom of its active layer each border on an adjacent contact layer that is more heavily doped than the active layer and that is made of the same material.

### BACKGROUND

Gunn diodes are semiconductor elements that are used mainly to generate high-frequency radiation in the GHz frequency range. Thanks to their low production costs and the relatively simple production work, Gunn diodes are employed in many areas of information technology in which high-frequency transmitters are needed.

The mode of operation of a Gunn diode is based on the so-called Gunn effect. This is a high-field-strength effect that occurs in certain semiconductor materials such as, for example, GaAs or InP. The energy bands of these semiconductors have relative maxima and minima at an energetic distance that is not very great. Electrons that were excited, for example, from a valence band into a conduction band are initially in the absolute minimum of the conduction band. Once these electrons in an electric field reach an energy level that lies in the range of the energy difference of the minima (with GaAs at 0.29 eV), they are then scattered by optical phonons into the adjacent minimum. Due to the high effective mass of the electrons in the adjacent minimum, the so-called side valley, they have less mobility there. The result is then a dropping current along with a rising voltage, i.e. a negative differential resistance.

This effect it utilized in the Gunn diode in that suitable circuitry causes electrons to accumulate and to migrate through the diode in bursts (like waves). This, in turn, causes an irradiation of electromagnetic waves corresponding to this frequency.

In actual practice, elements on the basis of this Gunn effect are usually produced as semiconductor elements using thin-layer technology, so that the requisite boundary conditions in terms of reproducible microscopic properties and the like can be fulfilled. The active part of such a Gunn diode, which determines the electric properties, is made up of three differently doped layers that are arranged on top of each other. Here, the middle layer constitutes the so-called active layer, since this is where the Gunn effect that is characteristic of the Gunn diode occurs. The two other layers are more heavily doped than the active layer.

In such an arrangement, due to the above-mentioned doping sequence and the resultant differences in conductivity, an electron domain is formed in the active layer where electrons accumulate as soon as a certain threshold field strength has been reached. As a rule, the same material is selected as the base material for the active layer and for the two adjacent contact layers, so that the crystallographic properties of the material remain unchanged over the boundary surface, and interferences due to crystal effects are largely avoided. The desired differences in the conductivity between the active layer and the adjacent contact layers are achieved exclusively through changes in the doping. As a rule, gallium arsenide (GaAs) or else indium phosphide (InP) are used as the base material.

The frequencies that are achieved and the output of a Gunn diode in such a construction depend, among other things, on the base material employed. On the other hand, especially in technological applications and in other semiconductor elements using thin-layer technology, the reproducibility of the component properties and also the general reliability under varying operating conditions are limited, among other things, by design-related restrictions such as, for example, the contact resistances. Moreover, it is precisely the stability and reliability of a Gunn diode that can be impaired by thermal heating of the elements or overheating on the one hand, and electromigration by and electric discharges in the ambient atmosphere on the other hand. Furthermore, if the contact resistances are too high, undesired operational interferences such as noise and the like can occur. Before this backdrop, efforts are being made to keep these effects as small as possible, particularly with an eye towards achieving broad technological applicability and industrial production possibilities.

### SUMMARY OF THE INVENTION

An aspect of the invention is to provide a Gunn diode of the above-mentioned type that has especially high-quality contacts with which the transition resistance or contact resistance is kept very low.

According to an aspect of the invention, the outer region of at least one of the contact layers consists of an outer contact layer that is made of the same material and that is even more heavily doped than the appertaining contact layer.

An aspect of the invention is based on the consideration that the contact resistance for an element of the above-mentioned type can be kept very low if individual contributing factors to the contact resistance are consistently minimized. Aside from the conductivity jump between a peripheral material, normally a metal, and the actual material of the layer adjacent to the active layer, it is also the case that an abrupt transition between two materials having a different crystal structure—due to the associated microscopic distortion effects—is also considered to be a significant contributing factor to the overall contact resistance. This transition can be kept very small in that, first of all, starting with the actual contact layer, an outer zone is provided that has the same crystal structure as the contact layer in order to avoid the above-mentioned distortion effects. For this purpose, the outer zone is likewise made of the same material as the actual contact layer. In order to facilitate the subsequent electric transition to the peripheral components, however, this outer zone should have a much higher conductivity than the actual contact layer. Towards this end, the above-mentioned outer zone is once again more heavily doped than the actual contact layer.

In an advantageous embodiment, the contacting layer that is even more heavily doped than the contact layer forms the anode contact.

In conventionally structured Gunn diodes, the layer packet consisting of the three above-mentioned differently doped layers is applied onto a substrate for which sapphire is normally used as the base material because of the dielectric properties and compatibility aspects with other components, but also because of aspects such as availability and processability and the like. In order to allow the contacting of the Gunn diode in both of the contact layers that are adjacent to the active layer, the contact layer that is adjacent to the substrate generally has a larger surface area than the actual active layer, so as to provide a surface portion of the lower contact layer that is not covered by the active layer and is thus accessible from above. Therefore, in such a construction, both electrodes of the Gunn diode are arranged on the same side of the substrate. The cathode contact is normally applied onto the upper, more heavily doped layer and the anode contact is applied onto the now-exposed top of the lower, more heavily doped layer.

In order to avoid detrimental and undesired electromigrations from the anode to the cathode, however, it is desirable to have an especially good spatial separation of the two electrodes from each other. Therefore, in a deliberate departure from the above-mentioned design, in which the two electrodes are located on the same side of the substrate and are thus close to each other, it is provided that one of the electrodes is positioned on the bottom of the substrate, that is to say, on the side facing away from the active layer packet. In order to make this possible, in an advantageous embodiment, the substrate with the adjacent contact layer is configured along the lines of a monolithic block made of the same material with heavier doping, so that essentially, one of the contact layers forms the substrate. As a result, a good spatial separation of the anode and cathode is possible without increasing the series resistance of the entire arrangement.

In another advantageous embodiment, the contact located on the substrate is attached to the bottom thereof. Here, the bottom is the side that is opposite from the active layer. In this manner, the largest possible spatial separation of the anode and cathode is achieved, limited by the dimensions of the diode. The electromigration from the anode to the cathode that occurs with conventional Gunn diodes and that results in the destruction of the element is thus kept very low.

Aside from the interferences caused by excessively high contact resistances, limits to the operational functionality and also to the service life of Gunn diodes can occur due to undesired thermal effects, especially heating of the elements of the Gunn diode. Moreover, Gunn diodes become frequency-unstable when exposed to excessive thermal heating, and in case of severe overheating, the negative differential resistance that is essential for the proper functioning of the Gunn diode disappears. In order to systematically counter this, in an advantageous embodiment, the active layer of the Gunn diode is recooled. For this purpose, it is thermally connected to a cooling element. This cooling element preferably has a high thermal conductivity and can thus dissipate thermal energy that is generated in the active layer.

In another advantageous embodiment, the thermal conductivity of the cooling element is higher than that of the substrate. This makes it possible to systematically dissipate the thermal energy via the cooling element. In order to also be able to systematically dissipate the thermal heat that is generated in the substrate, the thermal connection of the active layer to the cooling element is advantageously established via the substrate. This has the benefit that the heat energy that is generated in the substrate can also be dissipated via the cooling element. Since the heat is primarily generated in the active layer, it is also conceivable to dissipate the heat via the cathode contact in view of the shorter distance from the active layer.

When Gunn diodes are in operation, it is sometimes desirable to be able to regulate the cooling externally, both in terms of location as well as in terms of the point in time. For this purpose, the cooling element is advantageously configured as a cooling rod. This makes it possible to systematically use the cooling element in a way that is adapted to the thermal heating that actually occurs during the operation of the Gunn diode. Moreover, the use of a cooling rod allows the operation of the Gunn diodes at low temperatures since then the Gunn diode reacts even more sensitively to heating.

In order to also take heat generation at the cathode into account, in an advantageous embodiment, the cathode is surrounded by a dielectric shell. For this purpose, the Gunn diode is encapsulated and filled with a dielectric liquid having a high disruptive field strength and good thermal conductivity.

Another way to reduce the thermal heating of the active layer is to systematically limit the saturation current and thus the output of the Gunn diode. For this purpose, the active layer is advantageously limited laterally to a channel zone. Laterally, this channel zone is limited by a neutralized edge region. For this purpose, ions are preferably implanted in the edge region in order to achieve the neutralization of the active layer in the edge region. In spite of the lateral limitation of the active layer to a channel zone, the contact resistance of the cathode does not increase substantially in such a construction.

The cathode metallization is bombarded with positively charged ions due to the electric discharges in the air induced at high field strengths (E>150 kV/cm) during the operation of the Gunn diode. This can cause metal particles to separate from the cathode metallization and to accumulate on the exposed surface of the active layer. This can be detrimental to the operation of the Gunn diode or can even destroy it. In order to counter this, at least the surface of the active layer is advantageously provided with a passivation layer. In the usual configuration, the surface area as well as the height of the substrate are dimensioned larger than those of the active layer. Therefore, the substrate has a so-called mesa on which the active layer is situated. In order to minimize the deposition of the metal particles on the active layer, in an advantageous embodiment, the entire mesa is also provided with a passivation layer. This layer should have a disruptive field strength that is high enough to suppress the electric discharges in the air at high field strengths. In a dual function, the passivation layer also minimizes the surface current and thus prevents the deposition of the metal particles on the active layer.

Through the use of materials for the passivation layer that have a good thermal conductivity, the passivation layer can fulfill another function. In another advantageous embodiment, the passivation layer is thus configured as a cooling element. Suitable coatings with a good thermal conductivity in comparison to the active layer would be, for example, a diamond or boron nitride layer.

In another advantageous embodiment, the cathode contact of the Gunn diode can be provided with a protective coating. This protective coating should be made of a material that is relatively more resistant to ion bombardment than the cathode metallization that is to be protected. Preferably, molybdenum is used as the material for the protective coating.

In an especially preferred embodiment, the Gunn diode is built up on nitride-based materials (for example, GaN) or on oxide-based materials (for example, ZnO), so-called “wide band gap” materials. These serve as shared base materials on the basis of which the active layer as well as the adjacent contact layers and also the outer contact layer are produced, advantageously each with suitable doping. As was surprisingly found, much higher limit frequencies can be achieved with Gunn diodes on this material base than is the case with conventional GaAs or InP Gunn diodes. In order to be able to reduce the output of the nitride-based or oxide-based Gunn diode and thus to be able to provide even more stable and reliable diodes, in another advantageous embodiment, the Gunn diode is additionally provided with an aluminum fraction in certain zones or regions. Through a suitably selected aluminum fraction, the output of the Gunn diode can be reduced in order to increase its stability and service life.

Advantages of the invention include, through the provision of at least one of the contact layers with a comparatively more heavily doped outer contact layer, a possibility to spatially uncouple from each other the boundary surface factors that are responsible for the contact resistance, namely, a change of the crystal structures on the one hand, and a jump in the conductivities on the other hand. Here, along the lines of a first transition from a given contact layer into its outer contact layer, the conductivity can first be significantly increased, while retaining the crystal structure and thus avoiding crystal interferences, whereby subsequently, along the lines of a second transition, starting from the outer contact layer with a relatively high conductivity, it is possible to couple peripheral components, conducting wires or the like. Therefore, all in all, a total contact resistance or series resistance that is kept very low can be achieved which, in turn, accounts for very good component properties such as, for example, high thermal and electronic stability while avoiding interfering sources of noise and the like. Additional advantages lie in the lesser electromigration since both electrodes are installed so as to be spatially separated from each other and are situated on opposite surfaces of the Gunn diode. This is possible since one of the contact layers is used as the substrate. As a result, stable Gunn diodes can be produced that are impervious to electromigration and thus have an especially high output.

### BRIEF DESCRIPTION OF THE DRAWINGS

An embodiment of the invention will be explained in greater detail with reference to a drawing. This shows the following:

FIG. 1 a Gunn diode on the basis of GaN, and;

FIG. 2 a Gunn diode on the basis of GaN, with a laterally constricted active layer.

The same parts in the two figures are designated with the same reference numerals.

### DETAILED DESCRIPTION

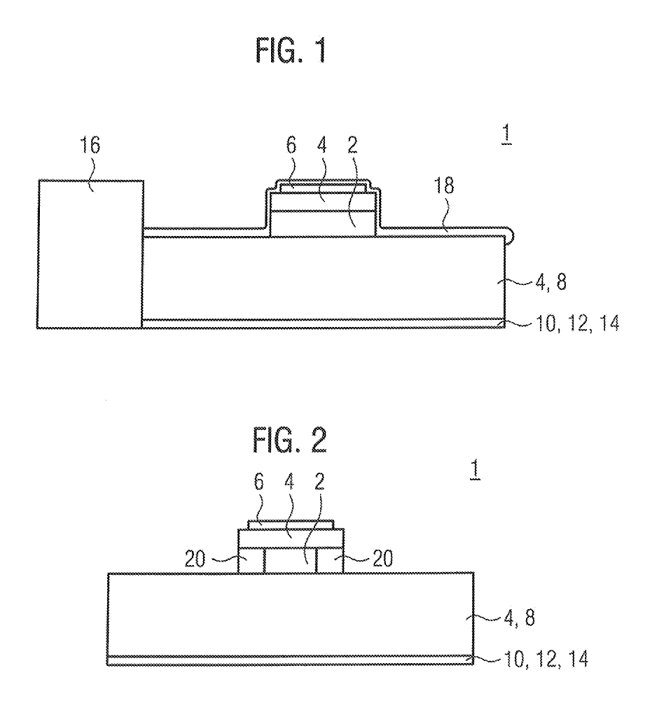

The Gunn diode 1 according to FIG. 1 is made using a thin-layer construction and, as the part that determines the electrical properties of the entire element, it has an n-doped so-called active layer 2, whereby, as the contact layer 4, a more heavily doped layer made of the same base material as the active layer 2 is adjacent to the top and bottom of said active layer 2. Here, GaN is provided as the base material so that, in comparison to conventional GaAs or InP Gunn diodes, much higher limit frequencies and outputs can be achieved. If necessary, the base material can still be provided with an aluminum fraction in selected suitable regions.

Embedding the active layer 2 between the two adjacent, more heavily doped contact layers 4 leads to the formation of electron domains at the cathode as a result of the Gunn effect. The cathode contact 6 is, in turn, applied onto the top of the more heavily doped contact layer 4 that is arranged on the active layer 2.

On the anode side and thus relative to the contact layer 4 arranged below the active layer 2, however, the contacting is not on the same side and thus on the top of the substrate 8 but rather, it is provided all the way through the substrate 8 on its rear side facing away from the layer packet. For this purpose, the lower, more heavily doped contact layer 4 is configured along the lines of a monolithic block as the substrate 8. The configuration of the lower contact layer 4 so as to form a substrate 8 especially allows a good spatial separation of the cathode contact 6 and of the anode contact 10 located on the rear. In this manner, electromigration effects from the anode contact 10 to the cathode contact 6 are suppressed.

The Gunn diode 1 is configured for especially high-quality and malfunction-free, low-noise operation. For this purpose, among other things, especially the contacting is selected in such a way that the contact resistances can be kept very low. In order to ensure this, the lower contact layer 4, which is configured as the substrate 8, has a lower outer region 12 that is provided in order to create the anode contact 10 and that consists of an outer contact layer 14 that is even more heavily n-doped than the actual contact layer 4 and that is made of the same base material, that is to say, likewise GaN. Thus, it can be achieved that, while retaining the crystal structure of the contact layer 4, the outer contact layer 14 has a relatively high conductivity thanks to which a relatively simple and reliable connection to peripheral components or the like can be established.

Through the special configuration of the anode contact 10, it is possible for the anode contacting to be carried out using stable materials, for example, molybdenum or tungsten, so that electromigration can be minimized. Ways to carry out the doping of the substrate 8 include, for example, diffusion, ion implantation or epitactic growth. The normal doping of the contact layers 4 is in the range from 1 to 50×10¹⁸ cm⁻³. The heavier doping of the outer contact layer 14 should be at least 10²⁰ cm⁻³.

For an especially reliable operation of the Gunn diode 1, the latter is also configured to minimize interferences or operational instabilities arising from dissipation effects or other thermal effects. In view of the realization that, in a Gunn diode of this design, heat loss is generated essentially in the active layer 2, the latter is thermally connected to a cooling element 16 made of a material with a relatively high thermal conductivity, especially a metal. In order to additionally be able to reliably dissipate any heat loss or the like from the substrate 8, the thermal connection of the active layer 2 to the cooling element 16, which can especially be configured as a cooling rod, is established via the substrate 8. For this purpose, the cooling element 16 is in direct physical contact with the substrate 8. However, it is also conceivable for the cooling element 16 to be in direct contact with the active layer 2, with the cathode contact 6 or with the anode contact 10.

For purposes of protection against damage and the like, the cathode contact 6 is also surrounded by a passivation layer 18, in the form of a dielectric shell.

FIG. 2 shows another embodiment of the invention. Similarly to FIG. 1, a contact layer 4 is adjacent to the top of the active layer 2, and this contact layer 4 has a cathode contact 6. The substrate 8 is adjacent to the bottom of the active layer 2 and it is made of the same material as the active layer 2, except that substrate 8 is more heavily doped than the active layer 2. The anode contact 10 is situated on the bottom of the substrate 8 and it is made of the same material as the substrate 8, except that once again, it is more heavily doped. In the embodiment according to FIG. 2, however, the active layer 2 is laterally limited to a prescribed channel region and, in each case, it is surrounded laterally by a neutral edge region 20. This can be achieved in that the edge region 20 of the active layer 2 is neutralized by the implantation of ions.

By reducing the size of the active layer 2, it is achieved that the saturation current of the Gunn diode 1 is reduced. This leads to lower thermal heating and thus to greater stability and longer service life of the Gunn diode 1.

### LIST OF REFERENCE NUMERALS

1 Gunn diode
2 active layer
4 contact layer
6 cathode contact
8 substrate
10 anode contact
12 outer region
14 outer contact layer
16 cooling element
18 passivation layer
20 edge region

1-16. (canceled)

17. A Gunn diode comprising:
an active layer having a top and a bottom;
a first contact layer disposed adjacent to the top of the active layer;
a second contact layer disposed adjacent to the bottom of the active layer, wherein the first and second contact layers are more heavily doped than the active layer; and
at least one outer contact layer disposed at an outer region of at least one of the first and second contact layers, the at least one outer contact layer being more heavily doped than the first and second contact layers, wherein the first and second contact layers, the active layer, and the at least one outer contact layer include a base material that is the same.

18. The Gunn diode as recited in claim 17, wherein the at least one outer contact layer includes an anode contact.

19. The Gunn diode as recited in claim 18, wherein one of the first and second contact layers includes a substrate.

20. The Gunn diode as recited in claim 19, wherein the anode contact is disposed on a bottom surface of the substrate.

21. The Gunn diode as recited in claim 19, further comprising a cooling element, wherein the active layer is thermally connected to the cooling element.

22. The Gunn diode as recited in claim 21, wherein a thermal conductivity of the cooling element is higher than a thermal conductivity of the substrate.

23. The Gunn diode as recited in claim 21, wherein the substrate thermally connects the active layer to the cooling element.

24. The Gunn diode as recited in claim 21, wherein the cooling element includes a cooling rod.

25. The Gunn diode as recited in claim 17, further comprising a cathode contact surrounded by a dielectric shell.

26. The Gunn diode as recited in claim 17, wherein the active layer is laterally limited to a channel zone laterally limited by a neutralized edge region.

27. The Gunn diode as recited in claim 17, further comprising a passivation layer disposed on at least a surface of the active layer.

28. The Gunn diode as recited in claim 27, wherein the passivation layer is configured to be a cooling element.

29. The Gunn diode as recited in claim 25, further comprising a protective coating disposed on the cathode contact.

30. The Gunn diode as recited in claim 17, wherein the base material is a nitride-based material.

31. The Gunn diode as recited in claim 17, wherein the base material is an oxide-based material.

32. The Gunn diode as recited in claim 17, wherein the base material includes an aluminum fraction.
